(19) United States
(12) Patent Application Publication
(10) Pub. No.: US 2017/0084771 A1
(43) Pub. Date: Mar. 23, 2017

(54) ANTIMONIDE-BASED HIGH BANDGAP TUNNEL JUNCTION FOR SEMICONDUCTOR DEVICES

(71) Applicant: The Boeing Company, Chicago, IL (US)

(72) Inventors: Philip T. Chiu, La Crescenta, CA (US); Moran Haddad, Granada Hills, CA (US); Richard R. King, Thousand Oaks, CA (US)

(21) Appl. No.: 14/860,214

(22) Filed: Sep. 21, 2015

(51) Int. Cl. H01L 31/0687; H01L 31/0693; H01L 31/0352; H01L 31/18; H01L 31/0304

(52) U.S. Cl. CPC H01L 31/0687; H01L 31/1844; H01L 31/03046; H01L 31/03042; H01L 31/035272; H01L 31/0693

(57) ABSTRACT

A tunnel junction for a semiconductor device is disclosed. The tunnel junction includes a n-doped tunnel layer and a p-doped tunnel layer. The p-doped tunnel layer is constructed of aluminum gallium arsenide antimonide (AlGaAsSb). A semiconductor device including the tunnel junction with the p-doped tunnel layer constructed of AlGaAsSb is also disclosed.

This disclosure was made with U.S. Government support under Contract No. ZFM-2-22051-01 awarded by the Department of Energy. The U.S. Government has certain rights in this disclosure.

### FIELD

The disclosed system and method relate to a semiconductor device and, more particularly, to a semiconductor device including a tunnel junction that has a n-doped tunnel layer and a p-doped tunnel layer, where the p-doped tunnel layer is constructed of aluminum gallium arsenide antimonide (AlGaAsSb).

### BACKGROUND

Wafer bonding technology may be used to monolithically join two materials with different lattice structures together. Wafer bonding technology has great potential. For example, joining gallium arsenide (GaAs) or indium phosphide (InP) based materials to other semiconductor materials may result in the integration of optical, photovoltaic, and electronic devices and enhance the performance of computers, solar cells, light emitting diodes and other electronic devices. In one specific example, a five junction (5J) cell, which is created by bonding a three junction (3J) GaAs-based cell with a two junction (2J) InP-based cell, results in a terrestrial solar cell having an efficiency of about 39% and a space solar cell having an efficiency of about 36%.

One requirement for an InP-based multi junction solar cell is a high transparency (which is also referred to as bandgap) tunnel junction. The tunnel junctions currently available that are employed in InP-based multi junction solar cells may sometimes absorb high amounts of light, or have very low peak tunneling currents. For example, one type of tunnel junction that is currently available includes a n-doped InP layer and a p-doped InAlGaAs layer. However, this tunnel junction may not always be easy to grow. This is because compounds containing a large amount of indium, such as InAlGaAs, are typically challenging to dope p-type. Furthermore, this type of tunnel junction may have a limited peak tunnel current as well. In another approach, a tunnel junction having a p-doped gallium arsenide antimonide (GaAsSb) layer and a n-doped indium gallium arsenide (InGaAs) layer may be used. This tunnel junction has a relatively high peak tunnel current, but both layers of this tunnel junction may also absorb light that is intended for active junctions of the solar cell. Thus, there exists a need in the art for a semiconductor device having a tunnel junction that is relatively easy to dope, has a relatively high transparency, and a relatively high peak tunnel current.

### SUMMARY

In one embodiment, a tunnel junction for a semiconductor device is disclosed. The tunnel junction includes a n-doped tunnel layer and a p-doped tunnel layer. The p-doped tunnel layer is constructed of aluminum gallium arsenide antimonide (AlGaAsSb).

In another embodiment, a semiconductor device is disclosed. The semiconductor device includes a first subcell, a second subcell, and a tunnel junction for electrically connecting the first subcell and the second subcell together in electrical series. The tunnel junction includes a n− doped tunnel layer and a p-doped tunnel layer. The p-doped tunnel layer is constructed of aluminum gallium arsenide antimonide (AlGaAsSb) and is doped with carbon.

In yet another embodiment, a method of constructing a photovoltaic device is disclosed. The method includes growth of a n-doped tunnel layer and a p-doped tunnel layer. The p-doped tunnel layer is constructed of aluminum gallium arsenide antimonide (AlGaAsSb).

Other objects and advantages of the disclosed method and system will be apparent from the following description, the accompanying drawings and the appended claims.

### BRIEF DESCRIPTION OF THE DRAWINGS

FIG. 1 is an illustration of an exemplary semiconductor device including the disclosed tunnel junction;

FIG. 2 is an illustration of an exemplary band offset diagram for the disclosed tunnel junction shown in FIG. 1;

FIG. 3 is the band offset diagram shown in FIG. 2 after thermal equilibrium;

FIG. 4 is a graph illustrating measured current and voltage for an exemplary tunnel junction after annealing;

FIG. 5 is an illustration of an alternative embodiment of the semiconductor device shown in FIG. 1 having a different n-doped tunnel layer;

FIG. 6 is an illustration of an exemplary band offset diagram for the disclosed tunnel junction shown in FIG. 5; and

FIG. 7 is the band offset diagram shown in FIG. 6 after thermal equilibrium.

### DETAILED DESCRIPTION

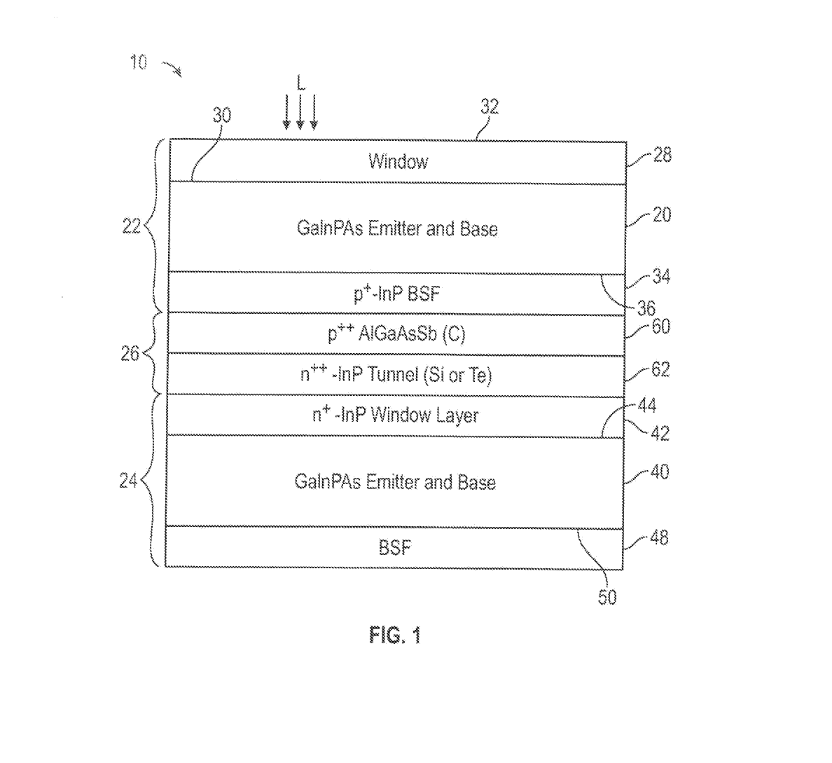

FIG. 1 is an illustration of an embodiment of the disclosed semiconductor device 10. In the embodiment as shown, the semiconductor device 10 is a solar cell, and in particular an indium phosphide (InP)-based dual-junction solar cell, meaning the semiconductor device 10 includes two photovoltaic cells (which are also referred to as subcells). Specifically, the semiconductor device 10 may include a first photovoltaic cell 22, a second photovoltaic cell 24, and the disclosed tunnel junction 26, which is located between the first photovoltaic cell 22 and the second photovoltaic cell 24. As explained in greater detail below, the tunnel junction 26 may include a n-doped tunnel layer and a p-doped tunnel layer, where the p-doped tunnel layer is constructed of aluminum gallium arsenide antimonide (AlGaAsSb). Furthermore, it should be appreciated that the tunnel junction 26 may be referred to as a p-n junction. Although FIG. 1 illustrates a solar cell, it is to be appreciated that the semiconductor device is not limited to just a solar cell. Indeed, the tunnel junction 26 may be used in a variety of optoelectronic devices such as, but not limited to, semiconductor lasers, laser power converters, and sensors.

The first photovoltaic cell 22 may include a first emitter and base 20. In one exemplary embodiment, the first emitter and base 20 is an indium gallium arsenide phosphide (GaInPAs) emitter. In another embodiment, the first emitter and base 220 may be III-V material such as, but not limited to, aluminum arsenide antimonide (AlAsSb), AlGaAsSb, aluminum indium arsenide (AlInAs), indium phosphide (InP), aluminum gallium indium arsenide (AlGaInAs), gallium indium arsenide (GaInAs), or gallium arsenide antimonide (GaAsSb). In one embodiment, the first emitter and base 20 includes a separate emitter layer and base layer (not shown), where the emitter layer is nearest to incident light.

In the non-limiting embodiment as shown, the first photovoltaic cell 22 includes a bandgap of 1.1 eV. In another embodiment, the first photovoltaic cell 22 may include a bandgap of from about 0.73 to 2.45 eV. In yet another embodiment, the first photovoltaic cell 22 may include a bandgap of from about 1.0 to 1.1 eV and may be included in a three or more junction solar cell. The first photovoltaic cell 22 may be sensitive to a first-photoactive-subcell-layer wavelength. As used herein, the term wavelength may mean a single discrete wavelength, or, wavelength may include a range of wavelengths at which the layer material achieves a good light-to-electricity conversion efficiency.

The first photovoltaic cell 22 may also include a window layer 28. The window layer 28 may be disposed on a first side 30 of the first emitter and base 20, which would be positioned nearest to incident light L. As used herein, the relative terms top and bottom are used to indicate the surface nearest to and farthest from the incident light L, respectively. Also, when used to compare two layers, upper or above or overlying may refer to a layer closer to the sun, and lower or below or underlying may refer to a layer further from the sun or other source of illumination. The window layer 28 may be an InP, AlGaInAs, AlInAs, AlAsSb, AlGaAsSb, or a GaInPAs composition that provides bandgap energy greater than about 1.1 eV. The window layer 28 has two functions. The first function of the window layer 28 is to reduce minority-carrier recombination (i.e., to passivate) on a front surface 32 of the first photovoltaic cell 22. Additionally, the optical properties of the window material must be such that as much light as possible is transmitted to the first photovoltaic cell 22, and any additional photoactive subcell layers that may be disposed underneath thereof (not shown), where the photogenerated charge carriers may be collected more efficiently. If there is substantial light absorption in the window layer 28, carriers generated in the window layer are less likely to be subsequently collected and hence light absorption in the window degrades overall conversion efficiency.

The semiconductor device 10 may optionally include an antireflection (AR) layer or coating (not shown) disposed on the front surface 32 of the semiconductor device 10 nearest the incident light L, which is shown impinging from the direction indicated by the arrows. In one embodiment, the AR coating may be disposed atop the window layer 28. The AR coating may reduce surface reflections between the optically transparent media above the semiconductor device 10 (such as air, glass, or polymer) and various semiconductor layers of the semiconductor device 10, thereby enabling more photons to enter the semiconductor device 10. The AR coating may be constructed of materials such as, for example, titanium dioxide (TiO₂), tantalum pentoxide (Ta₂O₅), silicon dioxide (SiO₂), and magnesium fluoride (MgF₂). The thickness of the AR coating may vary, but may range between about 0.04 and 0.35 microns. While an AR coating can be applied to the semiconductor device 10, in other embodiments another subcell may be stacked or applied above the semiconductor device 10.

The first photovoltaic cell 22 may further include a p-doped back surface field (BSF) layer 34 disposed on a bottom surface 36 of the first emitter and base 20. In the exemplary embodiment as illustrated, the p-doped BSF layer 34 is a p-doped InP BSF layer. In another embodiment, the p-doped BSF layer 34 may be an AlGaInAs, GaAsSb, AlAsSb, AlGaAsSb, AlInAs, GaInPAs and their alloys layer. In one embodiment, the BSF layer 34 is lattice-matched to InP. In another embodiment, the BSF layer 34 may be a coherently strained layer with a thickness below a Matthews-Blakeslee critical thickness.

The second photovoltaic cell 24 includes a second emitter and base 40. In the exemplary embodiment as shown, the second emitter and base 40 is a GaInPAs layer having an InP lattice constant. In another embodiment, the second emitter and base 40 may be GaInAs, GaAsSb, AlGaInAs, AlGaAsSb, GaInPAs and their alloys having an InP lattice constant. The second emitter and base 40 may have a bandgap lower than the bandgap of the first emitter and base 20. In the exemplary embodiment as shown in FIG. 1, the second photovoltaic cell 24 has a bandgap of about 0.8 eV. In another embodiment, the second photovoltaic cell 24 may have a bandgap of from about 0.73 to 2.0 eV. In yet another embodiment, the second photovoltaic cell 24 may have a bandgap of from about 0.73 to 0.8 eV and be included in a three or more junction solar cell lattice-matched to InP.

The second photovoltaic cell may 24 further include a n-doped window layer 42 disposed on a top surface 44 of the second emitter and base 40. In general, the characteristics of the n-doped window layer 42 are similar to the window characteristics of the window layer 28. The n-doped window 42 may include a n-doping concentration of between about 2×10¹⁸/cm³ and 2×10¹⁹/cm³. In another embodiment, the n-doped window 42 has a n-doping concentration of about 1×10¹⁹/cm³ to create a relatively large electric field and to passivate the p-n junction.

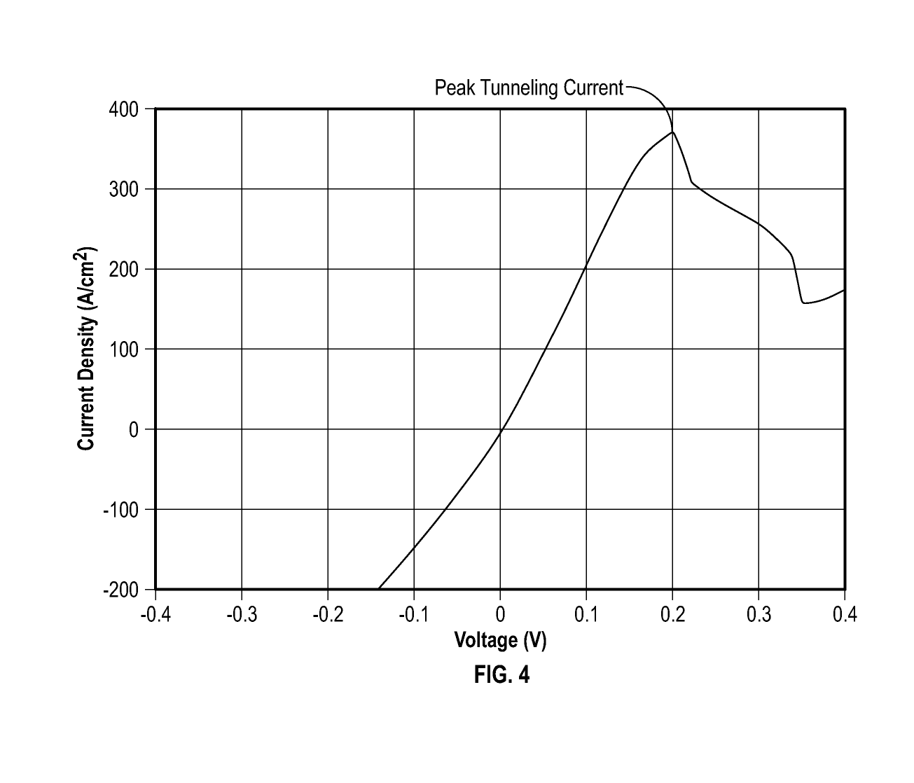

The second photovoltaic cell 24 may further include a second BSF layer 48 below the second emitter and base 40, which is similar to the BSF layer 34. The tunnel junction 26 may electrically connect the first photovoltaic cell 22 and the second photovoltaic cell 24 together with one another in electrical series. It should also be appreciated that the tunnel junction 26 is a type-II tunnel junction, which reduces the tunneling energy barrier within the tunnel junction 26. This in turn increases tunneling probability as well as the peak tunneling current of the tunnel junction 26. For example, as seen in FIG. 4, in one embodiment the tunnel junction 26 may include a peak tunneling current of 372 A/cm² and a specific resistance of 0.55 mΩ-cm². Furthermore, as explained in greater detail below, both layers of the tunnel junction 26 may be doped at relatively high levels.

In the embodiment as shown in FIG. 1, the tunnel junction 26 includes a p-doped tunnel layer 60 and a n-doped tunnel layer 62. The p-doped tunnel layer 60 is constructed of aluminum gallium arsenide antimonide (AlGaAsSb). The p-doped tunnel layer 60 may be doped with relatively high levels of carbon (i.e., C-doping or carbon doping). That is, the p-doped tunnel layer 60 may include a C-doping concentration ranging from about 10¹⁹/cm³ to 2×10²⁰/cm³. It is to be appreciated that carbon doping employs dopants that include relatively low diffusion coefficients, thereby resulting in relatively stable doping profiles and tunnel junction performance. However, an indium-based material such as, for example, an InAlGaAs layer may be challenging to dope because indium precursors may inhibit the incorporation of carbon dopants.

It should also be appreciated that the p-doped tunnel layer 60 may be lattice-matched with the p-doped InP BSF layer 34. The inclusion of antimonide in the p-doped tunnel layer 60 allows for lattice-matching with the p-doped InP BSF layer 34. Furthermore, the inclusion of aluminium within the p-doped tunnel layer 60 results in a relatively high bandgap (i.e., transparency) and a low level of light absorption. A relatively high bandgap may be any value greater than about 0.73 eV. In one embodiment, the p-doped tunnel layer 60 may include bandgap ranging from about 0.7 to about 1.4 eV.

The n-doped tunnel layer 62 may also be lattice-matched to InP. In one embodiment, the n-doped tunnel layer 62 is high bandgap III-V semiconductor having an InP lattice constant and that may form type II band alignment with the p-doped tunnel layer 60. In another embodiment, the n-doped tunnel layer 62 may be a highly n-doped InP, aluminium indium phosphide arsenic (AlInPAs), AlAsSb, or AlGaAsSb tunnel layer having a bandgap greater than or equal to 1.35 eV and an InP lattice constant. In one embodiment, the n-doped tunnel layer 62 is an InP tunnel layer having a bandgap of 1.35 eV. The n-doped tunnel layer 62 may be doped with relatively high levels of silicon or tellurium (i.e., Si or Te-doping). That is, the n-doped tunnel layer 62 may include an Si or Te-doping concentration of at least about 10¹⁹/cm³.

In one embodiment, the p-doped tunnel layer 60 and the n-doped tunnel layer 62 may be grown sequentially in a metalorganic vapor phase epitaxy (MOVPE) reactor. Furthermore, the semiconductor device 10 as well as various device components (e.g., the window, BSF) are grown in a MOVPE reactor. In another embodiment, the tunnel junction 26 may be grown in a chemical beam epitaxy (CBE), hydride vapor phase epitaxy (HVPE) or atomic layer deposition (ALD) reactor. In the embodiment as shown in FIG. 1, the semiconductor device 10 is an upright solar cell configuration where new layers are grown just above a prior layer, and the highest bandgap layer is grown last. In another embodiment, the semiconductor device 10 may be inverted, where the highest bandgap layer is grown first.

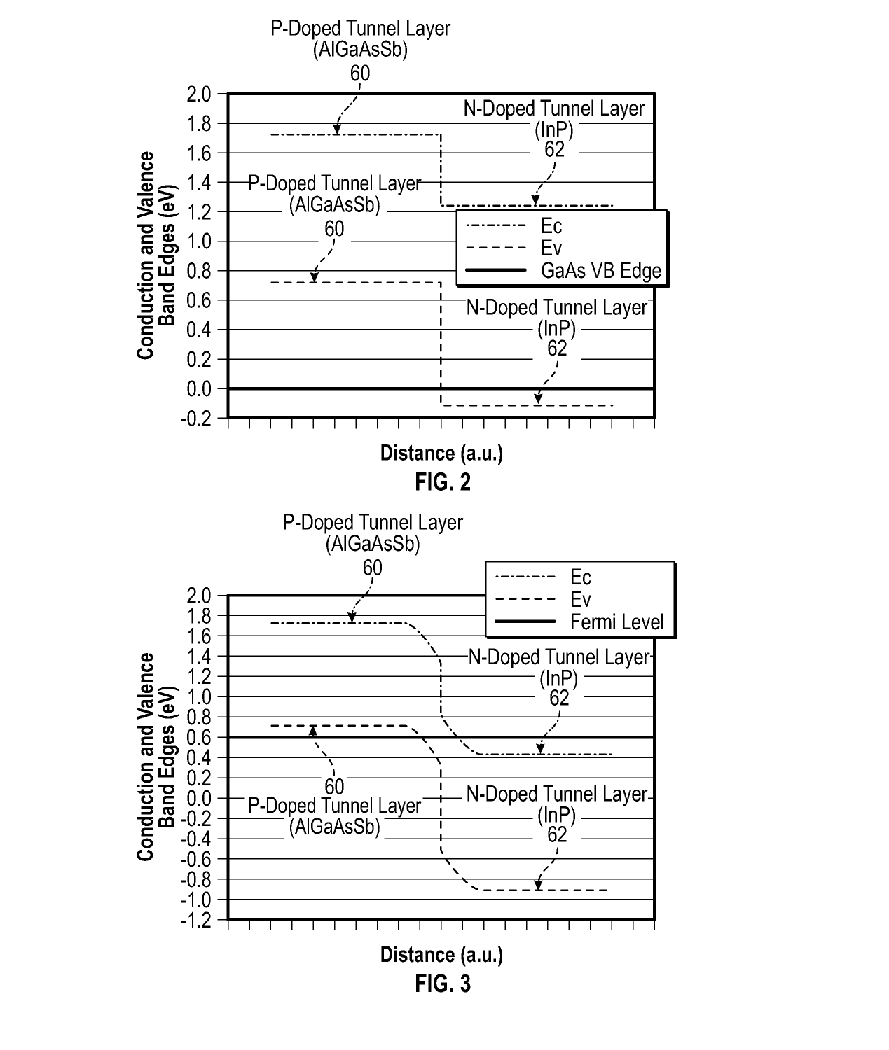

FIG. 2 is an illustration of an exemplary band offset diagram for the disclosed tunnel junction 26 (FIG. 1), and FIG. 3 is the band offset diagram shown in FIG. 2 after thermal equilibrium. The band offset diagrams shown in FIGS. 2-3 illustrate a valence band Eᵥ and a conduction band E_{c} of both the p-doped tunnel layer 60 as well as the n-doped tunnel layer 62 of the tunnel junction 26, as well as a valence band (VB) edge. In the exemplary embodiment as described, the p-doped tunnel layer 60 includes a 20% concentration of aluminium (i.e., x=0.20). Turning to FIG. 3 at thermal equilibrium, after carrier diffusion, it can be seen that both the valence band Eᵥ and the conduction band E_{c} both bend between the p-doped tunnel layer 60 and the n-doped tunnel layer 62. Joining the p-doped tunnel layer 60 and the n-doped tunnel layer 62 creates a staggered gap (type II) heterostructure. Indeed, as seen in FIGS. 3 and 4, both the valence band Eᵥ and the conduction band E_{c} of the n-doped tunnel layer 62 are lower in energy when compared to the p-doped tunnel layer 60. A heterojunction includes two or more semiconductor materials that are grown on one another, and a heterostructure includes the heterojunction. It should be appreciated that a type II heterostructure results in a lower effective energy barrier for tunneling.

FIG. 4 is a graph illustrating measured characteristics for an exemplary tunnel junction 26 after annealing. Specifically, the tunnel junction 26 was exposed to a thirty minute anneal at temperatures comparable to those experienced for active junction growth. It should be appreciated that there was negligible or no change in performance of the tunnel junction 26 before or after annealing, which is an indication that the dopants used for both the p-doped tunnel layer 60 and the n-doped tunnel layer 62 (FIG. 1) do not readily diffuse. As seen in FIG. 3, the tunnel junction 26 may include a peak tunneling current of 372 A/cm² and a specific resistance of 0.55 mΩ-cm². The peak tunneling current is equivalent to a solar cell operating at more than 30,000 suns, which is well in excess of a practical concentration.

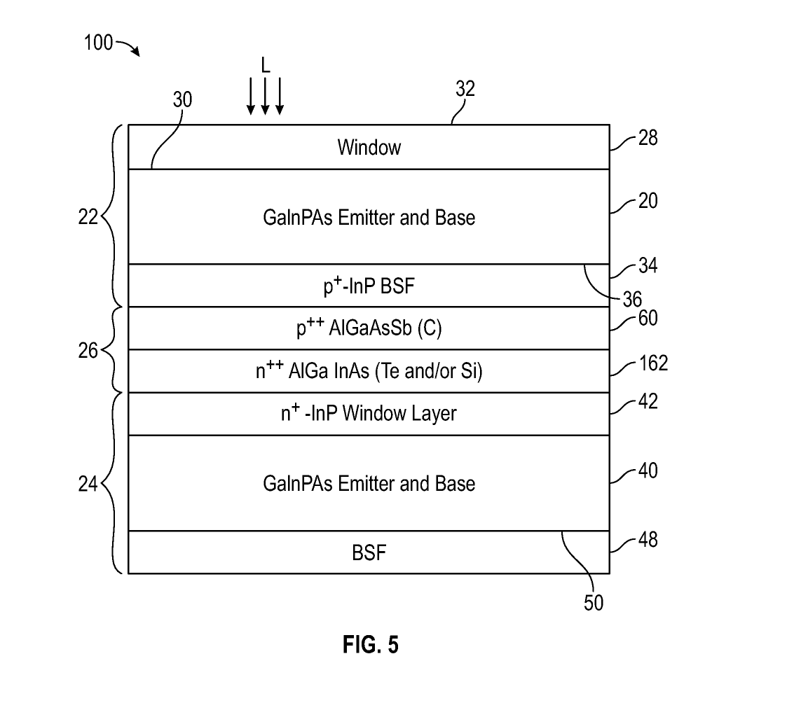

FIG. 5 is an alternative embodiment of a semiconductor device 100. The semiconductor device 100 includes a similar structure as the device shown in FIG. 1, except that a n-doped tunnel layer 162 is now constructed of AlGaInAs instead of InP. Thus, it is to be appreciated that the semiconductor device 100 retains the relatively high bandgap and the low level of light absorption of the p-doped tunnel layer 60 as described above and illustrated in FIG. 1. The n-doped tunnel layer 162 may be doped with relatively high levels of silicon, tellurium, or a combination of both materials. That is, the n-doped tunnel layer 62 may include a doping concentration of at least about 10¹⁹/cm³ of silicon, tellurium, or a combination of both materials.

It is to be appreciated that the n-doped tunnel layer 162 may include a lower bandgap and a higher light absorbance than the n-doped tunnel layer 62 (FIG. 1); however the lower bandgap of the n-doped tunnel layer 162 reduces the energy barrier to tunneling, which in turn exponentially increases the probability of tunneling and tunneling current density. Specifically, in one embodiment, the n-doped tunnel layer 162 may include a bandgap of about 0.73 eV. Furthermore, light absorption of the n-doped tunnel layer 162 may be mitigated by reducing the thickness of the n-doped tunnel layer, and by decreasing the Al content. Specifically, in one embodiment the thickness of the tunnel junction 26 may be reduced to a minimum of about 10 nm, and the amount of aluminium in the n-doped tunnel layer 162 may range from about zero (i.e., negligible amounts) to about 50%.

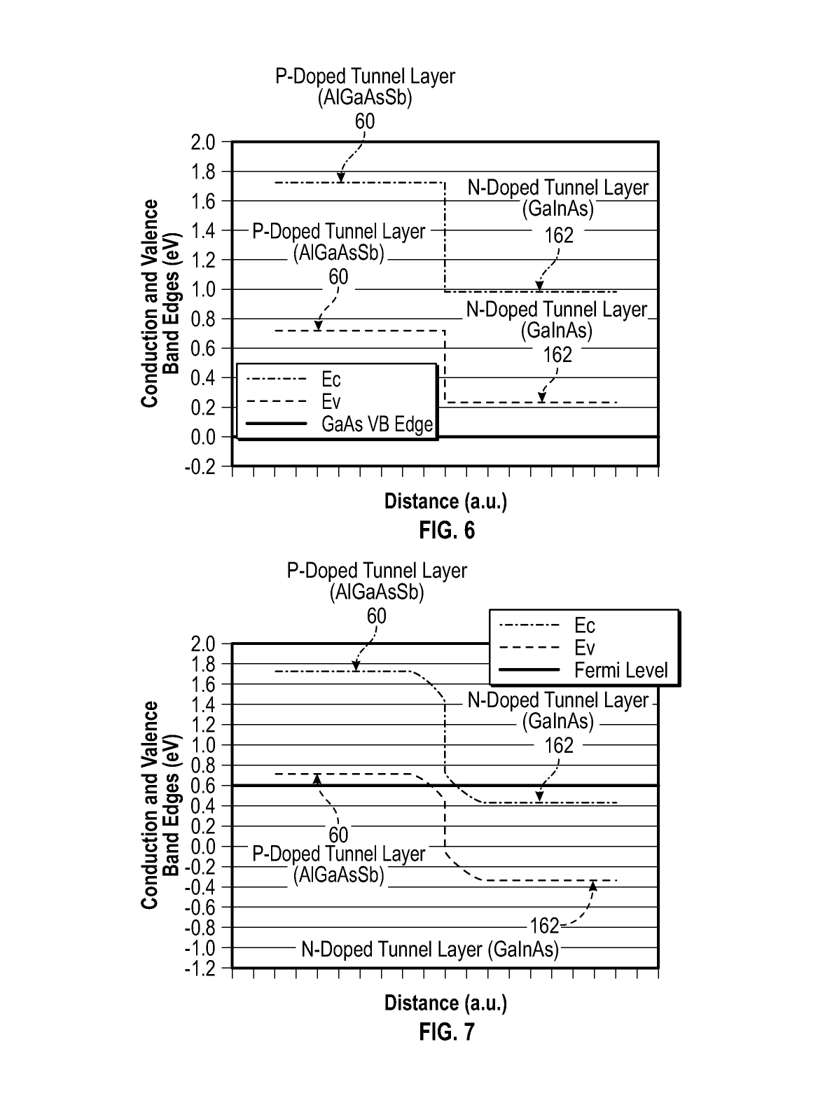

FIG. 6 is an illustration of an exemplary band offset diagram for the disclosed tunnel junction 26 shown in FIG. 5, and FIG. 7 is the band offset diagram shown in FIG. 7 after thermal equilibrium. In the exemplary embodiment as described, the p-doped tunnel layer 60 includes a 20% concentration of aluminium (i.e., x=0.20), and the n-doped tunnel layer 162 is constructed of GaInAs. However, it is to be understood that aluminium may be added to the n-doped tunnel layer 162 to create an n+ AlGaInAs layer as well.

Referring generally to the figures, the disclosed tunnel junction includes the p-doped tunnel layer constructed of AlGaAsSb, which demonstrates improved performance characteristics when compared to some other tunnel junctions currently available. Specifically, the disclosed p-doped layer may be easier to grow, since AlGaAsSb may be doped more heavily with carbon. In contrast, compounds containing a high amount of indium are typically challenging to dope. In fact, a p-doped InAlGaAs layer may only be capable of being doped to the level of about 10¹⁸/cm³, and even this level of doping may be challenging. Furthermore, the disclosed tunnel junction also exhibits relatively high peak tunneling currents. Finally, it should also be appreciated that the disclosed p-doped tunnel layer constructed of AlGaAsSb also exhibits a higher bandgap (i.e., transparency) than some other types of tunnel junctions currently available. Finally, it is to be appreciated that high transparency is especially important in applications where the tunnel junction is placed in the upper portion of a solar cell that is located closer to incident light (i.e., the sun).

While the forms of apparatus and methods herein described constitute preferred embodiments of this invention, it is to be understood that the invention is not limited to these precise forms of apparatus and methods, and that changes may be made therein without departing from the scope of the invention.

What is claimed is:

1. A tunnel junction for a semiconductor device, comprising:
a n-doped tunnel layer; and
a p-doped tunnel layer, wherein the p-doped tunnel layer is constructed of aluminum gallium arsenide antimonide (AlGaAsSb).

2. The tunnel junction of claim 1, wherein the p-doped tunnel layer is doped with carbon.

3. The tunnel junction of claim 2, wherein the p-doped tunnel layer includes a carbon concentration ranging from about 10¹⁹/cm³ to 2×10²⁰/cm³.

4. The tunnel junction of claim 1, wherein the p-doped tunnel layer includes bandgap ranging from about 0.7 to about 1.4 eV.

5. The tunnel junction of claim 1, wherein the n-doped tunnel layer is a n-doped material selected from the group consisting of: indium phosphide (InP), aluminium indium phosphide arsenic (AlInPAs), aluminum arsenide antimonide (AlAsSb), and AlGaAsSb.

6. The tunnel junction of claim 1, wherein the n-doped tunnel layer is doped with a material selected from a group consisting of: silicon and tellurium.

7. The tunnel junction of claim 6, wherein the n-doped tunnel layer includes a silicon concentration or a tellurium concentration of at least about 10¹⁹/cm³.

8. The tunnel junction of claim 1, wherein the n-doped tunnel layer is constructed of aluminum gallium indium arsenide (AlGaInAs).

9. The tunnel junction of claim 8, wherein the n-doped tunnel layer is doped with at least one of silicon and tellurium.

10. A semiconductor device, comprising:
a first subcell;
a second subcell; and
a tunnel junction for electrically connecting the first subcell and the second subcell together in electrical series, wherein the tunnel junction includes a n-doped tunnel layer and a p-doped tunnel layer, and wherein the p-doped tunnel layer is constructed of aluminum gallium arsenide antimonide (AlGaAsSb) and is doped with carbon.

11. The semiconductor device of claim 10, wherein the p-doped tunnel layer includes a carbon concentration ranging from about 10¹⁹/cm³ to 2×10²⁰/cm³.

12. The semiconductor device of claim 10, wherein the p-doped tunnel layer includes a bandgap ranging from about 0.7 to about 1.4 eV.

13. The semiconductor device of claim 10, wherein the n-doped tunnel layer is a n-doped material selected from the group consisting of: indium phosphide (InP), aluminium indium phosphide arsenic (AlInPAs), aluminum arsenide antimonide (AlAsSb), and AlGaAsSb.

14. The semiconductor device of claim 10, wherein the n-doped tunnel layer is doped with a material selected from a group consisting of: silicon and tellurium.

15. The semiconductor device of claim 14, wherein the n-doped tunnel layer includes a silicon concentration or a tellurium concentration of at least about 10¹⁹/cm³.

16. The semiconductor device of claim 10, wherein the n-doped tunnel layer is constructed of aluminum gallium indium arsenide (AlGaInAs).

17. The semiconductor device of claim 16, wherein the n-doped tunnel layer is doped with at least one of silicon and tellurium.

18. A method of constructing a photovoltaic device, comprising:
growing a n-doped tunnel layer; and
growing a p-doped tunnel layer, wherein the p-doped tunnel layer is constructed of aluminum gallium arsenide antimonide (AlGaAsSb).

19. The method as recited in claim 18, comprising doping the p-doped tunnel layer with carbon.

20. The method as recited in claim 18, wherein the n-doped tunnel layer and the p-doped tunnel layer are grown sequentially in a reactor selected from the group consisting of a: metalorganic vapor phase epitaxy (MOVPE) reactor, a chemical beam epitaxy (CBE) reactor, a hydride vapor phase epitaxy (HVPE) reactor and an atomic layer deposition (ALD) reactor.
